(19) United States
(12) Patent Application Publication
(10) Pub. No.: US 2024/0365551 A1
(43) Pub. Date: Oct. 31, 2024

(54) 3D NAND CELLS WITH ENHANCED ERASE SPEED THROUGH DIPOLE ENGINEERING AND METHODS OF MAKING THE SAME

(71) Applicant: Applied Materials, Inc., Santa Clara, CA (US)

(72) Inventors: Chang Seok Kang, Santa Clara, CA (US); Steven C. H. Hung, Sunnyvale, CA (US); Hsueh Chung Chen, Cohoes, NY (US); Naomi Yoshida, Sunnyvale, CA (US); Sung-Kwan Kang, San Jose, CA (US); Balasubramanian Pranatharthiharan, San Jose, CA (US)

(73) Assignee: Applied Materials, Inc., Santa Clara, CA (US)

(21) Appl. No.: 18/630,142

(22) Filed: Apr. 9, 2024

Related U.S. Application Data
(60) Provisional application No. 63/462,091, filed on Apr. 26, 2023.

(51) Int. Cl. H10B 43/35; H01L 21/67; H01L 23/528; H01L 23/532; H10B 43/20

(52) U.S. Cl. CPC H10B 43/35; H01L 21/67161; H01L 23/5283; H01L 23/53214; H01L 23/53257; H10B 43/20

(57) ABSTRACT

Exemplary semiconductor structures may include a substrate. The structures may include a first layer of silicon-and-oxygen-containing material overlying the substrate. The structures may include a second layer of silicon-and-oxygen-containing material. The structures may include a first layer of metal-and-oxygen-containing material between the first layer of silicon-and-oxygen-containing material and the second layer of silicon-and-oxygen-containing material. The first layer of metal-and-oxygen-containing material may include a first metal. The structures may include a second layer of metal-and-oxygen-containing material disposed within the first layer of metal-and-oxygen-containing material. The second layer of metal-and-oxygen-containing material may include a second metal. The structures may include a gate disposed within the second layer of metal-and-oxygen-containing material.

### CROSS-REFERENCE TO RELATED APPLICATIONS

This application claims the benefit of, and priority to U.S. Provisional Application Ser. No. 63/462,091, filed Apr. 26, 2023, which is hereby incorporated by reference in its entirety for all purposes.

### TECHNICAL FIELD

The present technology relates to semiconductor processes and materials. More specifically, the present technology relates to methods of forming semiconductor structures characterized by enhanced erase speed.

### BACKGROUND

3D NAND cells use trapped charges in layers of dielectric materials in order to store data. A first voltage may be applied to one or more of the layers of dielectric materials in order to write data, and a second voltage may be applied to erase data. In applying the second voltage, electrons may leak from a gate of the 3D NAND cell into the layers of dielectric used to trap charges. This may lead to slow or incomplete erasure of stored data. Thus, there is a need to develop a solution that may improve the speed and completeness of the deletion of data in 3D NAND cells.

### SUMMARY

Exemplary semiconductor structures may include a substrate. The structures may include a first layer of silicon-and-oxygen-containing material overlying the substrate. The structures may include a second layer of silicon-and-oxygen-containing material. The structures may include a first layer of metal-and-oxygen-containing material between the first layer of silicon-and-oxygen-containing material and the second layer of silicon-and-oxygen-containing material. The first layer of metal-and-oxygen-containing material may include a first metal. The structures may include a second layer of metal-and-oxygen-containing material disposed within the first layer of metal-and-oxygen-containing material. The second layer of metal-and-oxygen-containing material may include a second metal. The structures may include a gate disposed within the second layer of metal-and-oxygen-containing material.

In some embodiments, the first layer of metal-and-oxygen-containing material may be or include lanthanum oxide (La₂O₃). The first layer of metal-and-oxygen-containing material may be characterized by a thickness of less than or about 20 Å. The first layer of metal-and-oxygen-containing material may be or include yttrium oxide (Y₂O₃). The second layer of metal-and-oxygen-containing material may be or include aluminum oxide (Al₂O₃). The second layer of metal-and-oxygen-containing material may be characterized by a thickness of less than or about 100 Å. The second layer of metal-and-oxygen-containing material may be or include hafnium oxide (HfO₂). The first metal is characterized by a first work function. The second metal may be characterized by a second work function higher than the first work function. The gate may be or include a titanium-containing material, a tungsten-containing material, or a molybdenum-containing material. The titanium-containing material may be or include a titanium-and-nitrogen-containing material. The semiconductor structure may be a 3D NAND structure.

Some embodiments of the present technology may encompass semiconductor processing methods. The methods may include providing a substrate to a processing region of a semiconductor processing chamber. The substrate may include a first layer of silicon-and-oxygen-containing material and a second layer of silicon-and-oxygen-containing material spaced a distance apart from the first layer of silicon-and-oxygen-containing material. The methods may include forming a first layer of metal-and-oxygen-containing material overlying the second layer of silicon-and-oxygen-containing material. The first layer of metal-and-oxygen-containing material may include a first metal. The methods may include forming a second layer of metal-and-oxygen-containing material overlying the first layer of metal-and-oxygen-containing material. The second layer of metal-and-oxygen-containing material comprises a second metal. The methods may include forming a gate disposed within the second layer of metal-and-oxygen-containing material.

In some embodiments, the first layer of metal-and-oxygen-containing material and the second layer of metal-and-oxygen-containing material may be formed through atomic layer deposition (ALD). The first layer of metal-and-oxygen-containing material may be or include lanthanum oxide (La₂O₃). The first layer of metal-and-oxygen-containing material may be characterized by a thickness of less than or about 20 Å. The first layer of metal-and-oxygen-containing material may be or include yttrium oxide (Y₂O₃). The second layer of metal-and-oxygen-containing material may be or include aluminum oxide (Al₂O₃). The second layer of metal-and-oxygen-containing material may be characterized by a thickness of less than or about 100 Å.

Some embodiments of the present technology may encompass semiconductor processing systems. The systems may include a plurality of holding chambers. The systems may include a plurality of loading chambers configured to receive substrates into a vacuum environment. The systems may include an interface section having at least two interface transfer devices configured to deliver substrates between the plurality of holding chambers coupled with the interface section at a first location of the interface section and the plurality of loading chambers coupled with the interface section at a second location of the interface section opposite the plurality of holding chambers. The systems may include a plurality of process chambers. A first process chamber of the plurality of process chambers may be configured to deposit a first layer of metal-and-oxygen-containing material characterized by a first work function. A second process chamber of the plurality of processing chambers may be configured to deposit a second layer of metal-and-oxygen containing material characterized by a second work function greater than the first work function over the first layer of metal-and-oxygen-containing material.

In some embodiments, the first layer of metal-and-oxygen containing material may be or include lanthanum oxide (La₂O₃). The second layer of metal-and-oxygen containing material may be or include aluminum oxide (Al₂O₃).

Such technology may provide numerous benefits over conventional technology. For example, the present technology may increase the speed with which erase operations are performed in 3D NAND memory. Additionally, the present technology may increase the effectiveness of the erase operations. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

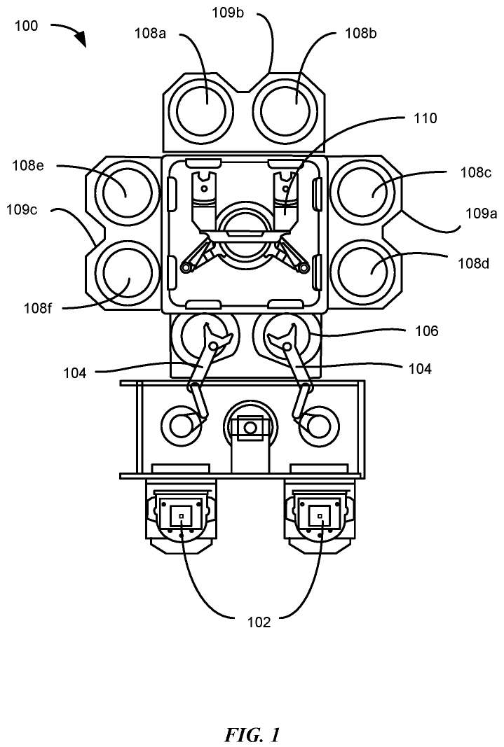

FIG. 1 shows a top plan view of one embodiment of an exemplary processing system according to some embodiments of the present technology.

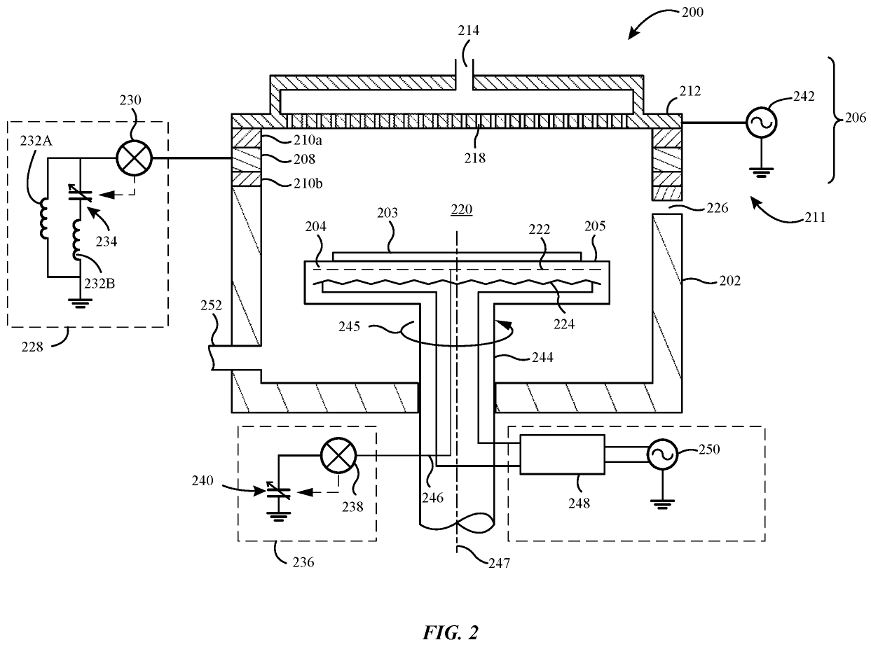

FIG. 2 shows a schematic diagram of an exemplary semiconductor processing system according to some embodiments of the present technology.

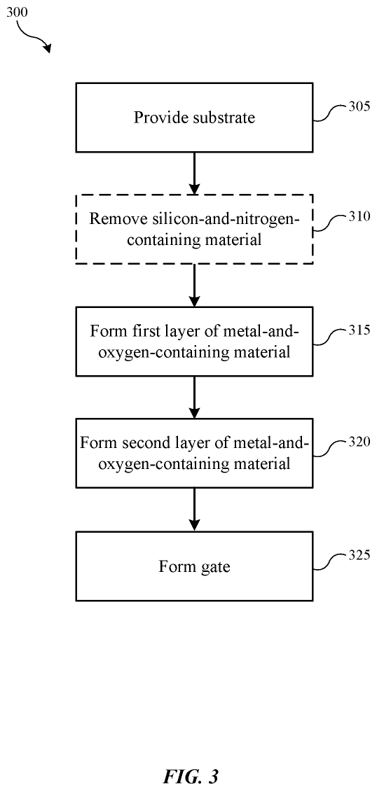

FIG. 3 shows exemplary operations in a method of semiconductor processing according to some embodiments of the present technology.

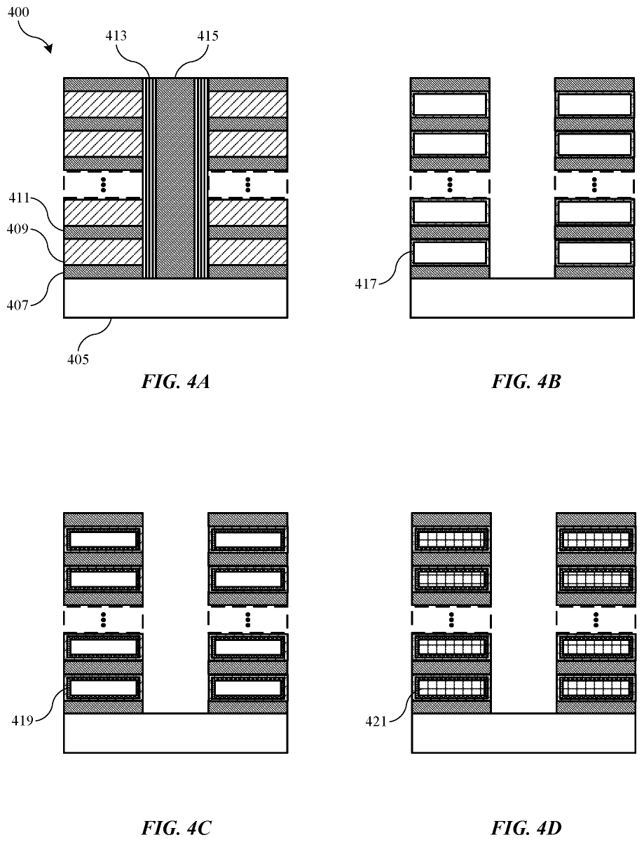

FIGS. 4A-4D show cross-sectional views of a substrate being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

3D NAND memory devices may be used to store information by capturing electrons in a memory cell, creating one or more bits of memory. The electrons may be captured within a trap layer by applying a write voltage to the memory cell. By applying the write voltage to the memory cell, electrons may be injected into the trap layer of the memory cell from a metal gate. The electrons may remain in the trap layer until an erase operation is performed on the memory cell. To perform the erase operation, an erase voltage may be applied to the memory cell. The erase voltage may force the electrons out of the trap layer, creating holes, or positively charged molecules within the trap layer. In many cases, a large voltage may be needed to perform the erase operation. In conventional technologies, because of the voltages necessary to perform the erase operation, and because the holes are positively charged, electrons may inadvertently flow from the gate to the trap layer during the erase operation. This electron flow, or back tunneling, may slow the erase operation and/or lead to unreliable erasure.

To suppress this unwanted back tunneling, the present technology may leverage work functions of one or more materials. A work function may be a property of a material, defined by the amount of energy needed to add or remove an electron from the material. A higher work function means that more energy is needed to add/remove an electron and a lower work function means that less energy is required. If a first material with a first work function overlies a second material with a second work function, an electron may only be able to flow in one direction. Thus, by layering two materials with different work functions, a dipole layer may be created.

In order to increase the speed at which a 3D NAND memory cell may be erased, a dipole layer may be formed between the gate and the trap layer. The dipole layer may be formed of two or more materials, such as metal oxides. A first layer of metal oxide may be formed over the trap layer and have a first work function. A second layer of metal oxide may then be formed over the first layer and have a second work function. The second work function may be higher than the first work function. Then, a gate may be formed within the second layer of metal oxide. Because the second layer is adjacent to the gate and has a higher work function than the first layer of metal oxide, electrons may be suppressed from flowing from the gate through the second and first layers of metal oxide under voltages typical of erase operations. Therefore, using a dipole layer may prevent unwanted electron flow and/or back tunneling from the gate to the trap layer, and the speed and reliability of the memory cell may be improved.

FIG. 1 shows a top plan view of one embodiment of a processing system 100 of deposition, etching, annealing, or other processing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-109c. A second robotic arm 110 may be used to transport the substrate wafers from the holding area 106 to the substrate processing chambers 108a-f and back. Each substrate processing chamber 108a-f, can be outfitted to perform a number of substrate processing operations including deposition processes described herein in addition to dry etching processes, removal processing, atomic layer deposition, chemical vapor deposition, physical vapor deposition, general etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be configured specifically to deposit dielectric material on the substrate as described below, and the third pair of processing chambers, e.g., 108a-b, may be used to etch the deposited dielectric. In another configuration, all three pairs of chambers, e.g., 108a-f, may be configured to deposit a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

FIG. 2 shows a cross-sectional view of an exemplary processing chamber 200 according to some embodiments of the present technology. The figure may illustrate an overview of a system incorporating one or more aspects of the present technology, and/or which may be specifically configured to perform one or more operations according to embodiments of the present technology. Additional details of chamber 200 or methods performed in the specifically configured chamber may be described further below. Chamber 200 may be utilized to form film layers according to some embodiments of the present technology, although it is to be understood that the methods may similarly be performed in any chamber within which film formation may occur. The processing chamber 200 may include a chamber body 202, a substrate support 204 disposed inside the chamber body 202, and a lid assembly 206 coupled with the chamber body 202 and enclosing the substrate support 204 in a processing volume 220. A substrate 203 may be provided to the processing volume 220 through an opening 226, which may be conventionally sealed for processing using a slit valve or door. The substrate 203 may be seated on a surface 205 of the substrate support during processing. The substrate support 204 may be rotatable, as indicated by the arrow 245, along an axis 247, where a shaft 244 of the substrate support 204 may be located. Alternatively, the substrate support 204 may be lifted up to rotate as necessary during a deposition process.

A plasma profile modulator 211 may be disposed in the processing chamber 200 to control plasma distribution across the substrate 203 disposed on the substrate support 204. The plasma profile modulator 211 may include a first electrode 208 that may be disposed adjacent to the chamber body 202, and may separate the chamber body 202 from other components of the lid assembly 206. The first electrode 208 may be part of the lid assembly 206, or may be a separate sidewall electrode. The first electrode 208 may be an annular or ring-like member, and may be a ring electrode. The first electrode 208 may be a continuous member around a circumference of the processing chamber 200 surrounding the processing volume 220, or may be discontinuous at selected locations if desired. The first electrode 208 may also be a perforated electrode, such as a perforated ring or a mesh electrode, or may be a plate electrode, such as, for example, a secondary gas distributor.

One or more isolators 210a, 210b, which may be a dielectric material such as a ceramic or metal oxide, for example aluminum oxide and/or aluminum nitride, may contact the first electrode 208 and separate the first electrode 208 electrically and thermally from a gas distributor 212 and from the chamber body 202. The gas distributor 212 may define apertures 218 for distributing process precursors into the processing volume 220. The gas distributor 212 may be coupled with a first source of electric power 242, such as an RF generator, RF power source, DC power source, pulsed DC power source, pulsed RF power source, or any other power source that may be coupled with the processing chamber. In some embodiments, the first source of electric power 242 may be an RF power source. In some embodiments the first source of electric power 242 may also be an inductively coupled plasma coil extending about inlet 214, and which may be used to produce or deliver plasma effluents into the processing volume 220.

The gas distributor 212 may be a conductive gas distributor or a non-conductive gas distributor. The gas distributor 212 may also be formed of conductive and non-conductive components. For example, a body of the gas distributor 212 may be conductive while a face plate of the gas distributor 212 may be non-conductive. The gas distributor 212 may be powered, such as by the first source of electric power 242 as shown in FIG. 2, or the gas distributor 212 may be coupled with ground in some embodiments.

The first electrode 208 may be coupled with a first tuning circuit 228 that may control a ground pathway of the processing chamber 200. The first tuning circuit 228 may include a first electronic sensor 230 and a first electronic controller 234. The first electronic controller 234 may be or include a variable capacitor or other circuit elements. The first tuning circuit 228 may be or include one or more inductors 232. The first tuning circuit 228 may be any circuit that enables variable or controllable impedance under the plasma conditions present in the processing volume 220 during processing. In some embodiments as illustrated, the first tuning circuit 228 may include a first circuit leg and a second circuit leg coupled in parallel between ground and the first electronic sensor 230. The first circuit leg may include a first inductor 232a. The second circuit leg may include a second inductor 232b coupled in series with the first electronic controller 234. The second inductor 232b may be disposed between the first electronic controller 234 and a node connecting both the first and second circuit legs to the first electronic sensor 230. The first electronic sensor 230 may be a voltage or current sensor and may be coupled with the first electronic controller 234, which may afford a degree of closed-loop control of plasma conditions inside the processing volume 220.

A second electrode 222 may be coupled with the substrate support 204. The second electrode 222 may be embedded within the substrate support 204 or coupled with a surface of the substrate support 204. The second electrode 222 may be a plate, a perforated plate, a mesh, a wire screen, or any other distributed arrangement of conductive elements. The second electrode 222 may be a tuning electrode, and may be coupled with a second tuning circuit 236 by a conduit 246, for example a cable having a selected resistance, such as 50 ohms, for example, disposed in the shaft 244 of the substrate support 204. The second tuning circuit 236 may have a second electronic sensor 238 and a second electronic controller 240, which may be a second variable capacitor. The second electronic sensor 238 may be a voltage or current sensor, and may be coupled with the second electronic controller 240 to provide further control over plasma conditions in the processing volume 220.

A third electrode 224, which may be a bias electrode and/or an electrostatic chucking electrode, may be coupled with the substrate support 204. The third electrode may be coupled with a second source of electric power 250 through a filter 248, which may be an impedance matching circuit. The second source of electric power 250 may be DC power, pulsed DC power, RF bias power, a pulsed RF source or bias power, or a combination of these or other power sources. In some embodiments, the second source of electric power 250 may be an RF bias power.

The lid assembly 206 and substrate support 204 of FIG. 1 may be used with any processing chamber for plasma or thermal processing. In operation, the processing chamber 200 may afford real-time control of plasma conditions in the processing volume 220. The substrate 203 may be disposed on the substrate support 204, and process gases may be flowed through the lid assembly 206 using inlet 214 according to any desired flow plan. Gases may exit the processing chamber 200 through an outlet 252, which may be coupled with a pump, such as any exhaust pump, including a turbomolecular pump in some embodiments. Electric power may be coupled with the gas distributor 212 to establish a plasma in the processing volume 220. The substrate may be subjected to an electrical bias using the third electrode 224 in some embodiments.

Upon energizing a plasma in the processing volume 220, a potential difference may be established between the plasma and the first electrode 208. A potential difference may also be established between the plasma and the second electrode 222. The electronic controllers 234, 240 may then be used to adjust the flow properties of the ground paths represented by the two tuning circuits 228 and 236. A set point may be delivered to the first tuning circuit 228 and the second tuning circuit 236 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 228, 236 may have a variable impedance that may be adjusted using the respective electronic controllers 234, 240. Where the electronic controllers 234, 240 are variable capacitors, the capacitance range of each of the variable capacitors, and the inductances of the first inductor 232a and the second inductor 232b, may be chosen to provide an impedance range. This range may depend on the frequency and voltage characteristics of the plasma, which may have a minimum in the capacitance range of each variable capacitor. Hence, when the capacitance of the first electronic controller 234 is at a minimum or maximum, impedance of the first tuning circuit 228 may be high, resulting in a plasma shape that has a minimum aerial or lateral coverage over the substrate support. When the capacitance of the first electronic controller 234 approaches a value that minimizes the impedance of the first tuning circuit 228, the aerial coverage of the plasma may grow to a maximum, effectively covering the entire working area of the substrate support 204. As the capacitance of the first electronic controller 234 deviates from the minimum impedance setting, the plasma shape may shrink from the chamber walls and aerial coverage of the substrate support may decline. The second electronic controller 240 may have a similar effect, increasing and decreasing aerial coverage of the plasma over the substrate support as the capacitance of the second electronic controller 240 may be changed.

The electronic sensors 230, 238 may be used to tune the respective circuits 228, 236 in a closed loop. A setpoint for current or voltage, depending on the type of sensor used, may be installed in each sensor, and the sensor may be provided with control software that determines an adjustment to each respective electronic controller 234, 240 to minimize deviation from the setpoint. Consequently, a plasma shape may be selected and dynamically controlled during processing. It is to be understood that, while the foregoing discussion is based on electronic controllers 234, 240, which may be variable capacitors, any electronic component with adjustable characteristic may be used to provide tuning circuits 228 and 236 with adjustable impedance.

FIG. 3 shows exemplary operations in a processing method 300 according to some embodiments of the present technology. The method may be performed in a variety of processing chambers, including processing chamber 200 described above, which may be incorporated on system 100, for example. Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 300 may describe operations shown schematically in FIGS. 4A-4D, the illustrations of which will be described in conjunction with the operations of method 300. In some embodiments, FIGS. 4A-4D may represent a 3D NAND structure. It is to be understood that the figures illustrate only partial schematic views, such as partial schematic views of a 3D NAND structure, and a substrate may contain any number of structural sections having aspects as illustrated in the figures, as well as alternative structural aspects that may still benefit from operations of the present technology.

Method 300 may include additional operations prior to initiation of the listed operations. For example, additional processing operations may include forming structures on a semiconductor substrate, which may include both forming and removing material. Additionally or alternatively, material removal may be performed, such as reduction of native oxides or etching of material, or any other operation that may prepare one or more exposed surfaces of substrate or exposed materials formed on the substrate. Prior processing operations may be performed in the chamber in which method 300 may be performed, or processing may be performed in one or more other processing chambers prior to delivering the substrate into the semiconductor processing chamber in which method 300 may be performed. Regardless, method 300 may optionally include delivering a substrate to a processing region of a semiconductor processing chamber, such as processing chamber 200 described above, or other chambers that may include components as described above. The substrate may be positioned on a substrate support, which may be a pedestal such as substrate support 204, and which may reside in a processing region of the chamber, such as processing volume 220 described above. An exemplary structure 400 is illustrated in FIG. 4A, and may be or include aspects of a substrate 405 on which operations according to the present technology may be performed.

Method 300 may include providing the substrate 405 to a processing region of a semiconductor processing chamber at operation 305. The substrate 405 may be any number of materials on which materials may be deposited. The substrate 405 may be or include silicon, germanium, dielectric materials including silicon oxide or silicon nitride, metal materials, or any number of combinations of these materials. The substrate 405 may include alternating layers of silicon-containing material and silicon-and-nitrogen-containing material. For example, a first layer of silicon-and-oxygen-containing material 407 may be formed overlying the substrate 405. A first layer of silicon-and-nitrogen-containing material 409 formed overlying the first layer of silicon-and-oxygen-containing material 407. Together, the first layer of silicon-and-oxygen-containing material 407 and the first layer of silicon-and-nitrogen-containing material 409 may form one set of alternating layers of a stack of alternating layers on the substrate 405. A second layer of silicon-and-oxygen-containing material 411 may be formed overlying the first layer of silicon-and-nitrogen-containing material 409. Any number of alternating layers of silicon-and-oxygen-containing material and silicon-and-nitrogen-containing material may be formed on the substrate 405. In some embodiments, portions of the alternating layers of silicon-and-oxygen-containing material and/or the silicon-and-nitrogen-containing material may be removed to form stair-like features on the substrate 405. While structure 400 only depicts four sets of alternating layers of the stack of alternating layers on the substrate 405, any number of sets are contemplated. For example, the overall stack may include any number of sets of layers including greater than or about 2 sets, greater than or about 10 sets, greater than or about 50 sets, greater than or about 100 sets, or more sets of layers. Any specific number of sets encompassed by any of these stated ranges is to be understood as if specifically stated here, and the figure is included merely to illustrate an exemplary structure.

The thicknesses of the layers may be any range of thicknesses to produce memory or other semiconductor structures, such as 3D NAND structures. For example, in some embodiments, the layers of silicon-and-oxygen-containing material and/or silicon-and-nitrogen-containing material may be less than or about 100 nm, and may be less than or about 90 nm, less than or about 80 nm, less than or about 70 nm, less than or about 60 nm, less than or about 50 nm, less than or about 45 nm, less than or about 40 nm, less than or about 35 nm, less than or about 30 nm, less than or about 25 nm, less than or about 20 nm, less than or about 15 nm, less than or about 10 nm, or less. In some embodiments, thickness of the silicon-and-nitrogen-containing material may be increased relative to the silicon-and-oxygen-containing material to allow deposition of multiple materials in addition to the gate material. The layers of silicon-and-nitrogen-containing material may be characterized by a thickness that is greater than or about 1 nm thicker than the adjacent silicon-and-oxygen-containing material, such as greater than or about 2 nm, greater than or about 3 nm, greater than or about 4 nm, greater than or about 5 nm, greater than or about 6 nm, greater than or about 7 nm, greater than or about 8 nm, greater than or about 9 nm, greater than or about 10 nm, or more.

The substrate 405 may also include one or more features etched through the stack of alternating layers on the substrate 405. The features may be high aspect ratio memory holes extending through each layer of silicon-and-oxygen-containing material and each layer of silicon-and-nitrogen-containing material. Within the memory holes, one or more layers of material may be deposited along sidewalls of the features. As shown in FIG. 4A, one or more layers of material may be formed within the features. For example, an ONOP stack 413 may be formed within the feature. The ONOP stack 413 may include a layer of silicon oxide (O) in contact with the alternating layers of silicon-and-oxygen-containing material 407 and silicon-and-nitrogen-containing material 409. A layer of silicon nitride (N) may be adjacent to the layer of silicon oxide. A layer of silicon oxide (O) may be formed to the layer of silicon nitride, and a layer of polysilicon (P) may be adjacent to the fourth layer of silicon oxide. Additionally, a silicon oxide channel layer 415 may be formed within the feature and may be disposed between the polysilicon of the ONOP stack 413.

The method 300 may include removing the silicon nitride layer 409 at optional operation 310, as illustrated in FIG. 4B. However, this operation could be performed prior to initiation of method 300 such as during the optional processing prior to method 300. Accordingly, the substrate 405 provided at operation 305 may already have silicon-and-nitrogen-containing material removed. However, if the silicon-and-nitrogen-containing material is present on the substrate 405, optional operation 310 may include an etching or other removal process to remove the silicon-and-nitrogen-containing material. A number of removal operations may be performed, and in some embodiments a wet etch process, a dry etch process, or any other etch process useful in semiconductor processing may be performed to remove the silicon-and-nitrogen-containing material. After the etching has been performed, voids may be present between layers of silicon-containing material.

As shown in FIG. 4B, the method 300 may include forming a first layer of metal-and-oxygen-containing material 417 at operation 315. The first layer of metal-and-oxygen-containing material 417 may be between the first layer of silicon-and-oxygen-containing material 407 and the second layer of silicon-and-oxygen-containing material 411. More specifically, the first layer of metal-and-oxygen-containing material 417 may be in contact with both the first layer of silicon-and-oxygen-containing material 407 and the second layer of silicon-and-oxygen-containing material 411 and may define a void region. The first layer of metal-and-oxygen-containing material 417 may be formed by any deposition method including, but not limited to, atomic layer deposition (ALD), chemical vapor deposition (CVD), or plasma-enhanced chemical vapor deposition (PECVD).

The first layer of metal-and-oxygen-containing material 417 may be characterized by a thickness of less than or about 20 Å, and may be characterized by a thickness of less than or about 18 Å, less than or about 16 Å, less than or about 14 Å, less than or about 12 Å, less than or about 10 Å, less than or about 9 Å, less than or about 8 Å, less than or about 7 Å, less than or about 6 Å, less than or about 5 Å, less than or about 4 Å, less than or about 3 Å, or less.

The first layer of metal-and-oxygen-containing material 417 may include a first metal and, in some embodiments, may include a plurality of metals. In embodiments, the first metal may be or include, but is not limited to, hafnium, lanthanum, or yttrium. Accordingly, the first layer of metal-and-oxygen-containing material 417 may be, for example, hafnium oxide (HfO₂), lanthanum oxide (La₂O₃), or yttrium oxide (Y₂O₃). The first metal, or the plurality of metals in the first layer of metal-and-oxygen-containing material 417, may be characterized by a first work function. The first work function may be less than or about 4.0 cV, less than or about 3.9 cV, less than or about 3.8 cV, less than or about 3.7 cV, less than or about 3.6 cV, less than or about 3.5 cV, less than or about 3.4 cV, less than or about 3.3 eV, less than or about 3.2 cV, less than or about 3.1 cV, less than or about 3.0 eV, or less. For example, the work function of hafnium is approximately 3.9 cV, the work function of lanthanum is approximately 3.5 cV, and the work function of yttrium is approximately 3.1 eV. While hafnium, lanthanum, and yttrium are discussed, any metal is contemplated.

As shown in FIG. 4C, the method 300 may then include forming a second layer of metal-and-oxygen-containing material 419 at operation 320. The second layer of metal-and-oxygen-containing material 419 may be disposed within the first layer of metal-and-oxygen-containing material 417. More specifically, the second layer of metal-and-oxygen-containing material 419 may be in contact with the first layer of metal-and-oxygen-containing material 417 and may define a void region. Similar to the first layer of metal-and-oxygen-containing material 417, the second layer of metal-and-oxygen-containing material 419 may be formed by any deposition method including, but not limited to, ALD, CVD, or PECVD. In embodiments, the second layer of metal-and-oxygen-containing material 419 may be deposited in the same manner as the first layer of metal-and-oxygen-containing material 417 although different deposition methods are contemplated.

The second layer of metal-and-oxygen-containing material 419 may be characterized by a thickness of less than or about 100 Å, and may be characterized by a thickness of less than or about 90 Å, less than or about 80 Å, less than or about 70 Å, less than or about 60 Å, less than or about 50 Å, less than or about 45 Å, less than or about 40 Å, less than or about 35 Å, less than or about 30 Å, less than or about 25 Å, less than or about 20 Å, less than or about 15 Å, less than or about 10 Å, or less. In embodiments, the second layer of metal-and-oxygen-containing material 419 may be characterized by a greater thickness than the first layer of metal-and-oxygen-containing material 417.

The second layer of metal-and-oxygen-containing material 419 may include a second metal and, in some embodiments, may include a plurality of metals. In embodiments, the second metal may be or include, but is not limited to, aluminum, hafnium, or lanthanum. Accordingly, the second layer of metal-and-oxygen-containing material 419 may be, for example, aluminum oxide (Al₂O₃), hafnium oxide (HfO₂), or lanthanum oxide (La₂O₃). The second metal may be different than the first metal such that the second metal may be characterized by a second work function that differs from the first work function. More specifically, the second work function may be greater than the first work function. For example, the second work function may be greater than or about 3.0 eV, greater than or about 3.1 eV, greater than or about 3.2 eV, greater than or about 3.3 eV, greater than or about 3.4 eV, greater than or about 3.5 eV, greater than or about 3.6 eV, greater than or about 3.7 eV, greater than or about 3.8 eV, greater than or about 3.9 eV, greater than or about 4.0 eV, greater than or about 4.1, or more. For example, the work function of aluminum is approximately 4.1 eV, the work function of hafnium is approximately 3.9 eV, and the work function of lanthanum is approximately 3.5 eV. While aluminum, hafnium, and lanthanum are discussed, any metal is contemplated so long as the second work function is greater than the first work function.

In embodiments, the second metal may be characterized by a greater Fermi level than the first metal. Increased Fermi levels attract electrons more strongly than reduced Fermi levels. Accordingly, during erase operations, electrons ejected from the structure 400, such as the gate described below, may repelled from the first layer of metal-and-oxygen-containing material 417. Therefore, electrons may be attracted to the second layer of metal-and-oxygen-containing material 419 characterized by a greater Fermi level. This difference in Fermi level may suppress electron flow from the gate and may improve erase speed.

As shown in FIG. 4D, the method 300 may include forming a metal-containing layer 421, which may be a gate in a 3D NAND structure, at operation 325. The metal-containing layer 421 may be disposed within the second layer of metal-and-oxygen-containing material 419, such as within the void defined by the second layer of metal-and-oxygen-containing material 419. The metal-containing metal layer 421 may include titanium, tungsten, molybdenum, or any other appropriate metal. The metal layer 421, the first layer of metal-and-oxygen-containing material 417, and the second layer of metal-and-oxygen-containing material 419 may be formed in the void created by the removal of the silicon-and-nitrogen-containing material 409 at optional operation 310. The metal-containing layer 421 may thus be a gate that may be configured to allow charges to flow into/out of a memory cell.

Compared to conventional technologies, the gate may only be surrounded by one metal oxide material. Conversely, the first layer of metal-and-oxygen-containing material 417 and the second layer of metal-and-oxygen-containing material 419 of the present technology may form a dipole layer in the memory cell. The dipole layer may more easily permit charges, such as electrons, to move in one direction than the other, such as allowing charges to flow from channel to gate while suppressing charges from to flow from gate to channel, which may be referred to as back tunneling. For example, if the first metal includes lanthanum and the second metal includes aluminum, the work functions of each metal may be 3.5 eV and 4.1 eV, respectively. During an erase operation of the memory cell, a “hole,” or lack of an electron may be generated in one or more of the layers of the memory cell by applying a voltage to one or more of the layers shown and described in FIGS. 4A-4D. In embodiments, for example, the hole may have a barrier of approximately 4.4 cV. Thus, a charge at the metal-containing layer 421, or gate, may be drawn to the hole. However, because the second layer of metal-and-oxygen-containing material 419 is characterized by a smaller work function than the first layer of metal-and-oxygen-containing material 417, the charge may be repelled by the dipole layer. By counter example, if the first layer of metal-and-oxygen-containing material 417 had a work function higher than the second layer of metal-and-oxygen-containing material 419, the charge may be drawn from the metal-containing layer 421 or gate into the memory cell. The charge may then be drawn by the hole, and the erase operation may be slowed and/or less effective. By configuring the dipole layer such that the second layer of metal-and-oxygen-containing material 419 has a higher work function than that of the first layer of metal-and-oxygen-containing material 411 and placing the metal-containing layer 421 within the second layer of metal-and-oxygen-containing material 419, electron flow from the metal-containing layer 421 into the memory cell may be suppressed. Accordingly, the dipole layer of the present technology may suppress back tunneling and improve erase speed. Conventional technologies may suffer from back tunneling and poor erase speeds compared to the present technology.

The present technology also encompasses semiconductor processing systems. The systems may include a plurality of holding chambers, such as pods 102. A plurality of loading chambers may receive substrates into a vacuum environment, such as area 104. An interface section having at least two interface transfer devices, such as robotic arms 104 and 106, may be configured to deliver substrates between the plurality of holding chambers coupled with the interface section at a first location of the interface section and the plurality of loading chambers coupled with the interface section at a second location of the interface section opposite the plurality of holding chambers. The systems may include a plurality of process chambers, such as chambers 108a-f. A first process chamber of the plurality of process chambers may be configured to deposit a first layer of metal-and-oxygen containing material, such as lanthanum oxide (La₂O₃), characterized by a first work function. A second process chamber of the plurality of processing chambers may be configured to deposit a second layer of metal-and-oxygen containing material, such as aluminum oxide (Al₂O₃), characterized by a second work function greater than the first work function over the first layer of metal-and-oxygen-containing material.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor structure comprising:
a substrate;
a first layer of silicon-and-oxygen-containing material overlying the substrate;
a second layer of silicon-and-oxygen-containing material;
a first layer of metal-and-oxygen-containing material between the first layer of silicon-and-oxygen-containing material and the second layer of silicon-and-oxygen-containing material, wherein the first layer of metal-and-oxygen-containing material comprises a first metal;
a second layer of metal-and-oxygen-containing material disposed within the first layer of metal-and-oxygen-containing material, wherein the second layer of metal-and-oxygen-containing material comprises a second metal; and
a gate disposed within the second layer of metal-and-oxygen-containing material.

2. The semiconductor structure of claim 1, wherein the first layer of metal-and-oxygen-containing material comprises lanthanum oxide (La₂O₃).

3. The semiconductor structure of claim 1, wherein the first layer of metal-and-oxygen-containing material is characterized by a thickness of less than or about 20 Å.

4. The semiconductor structure of claim 1, wherein the first layer of metal-and-oxygen-containing material comprises yttrium oxide (Y₂O₃).

5. The semiconductor structure of claim 1, wherein the second layer of metal-and-oxygen-containing material comprises aluminum oxide (Al₂O₃).

6. The semiconductor structure of claim 1, wherein the second layer of metal-and-oxygen-containing material is characterized by a thickness of less than or about 100 Å.

7. The semiconductor structure of claim 1, wherein the second layer of metal-and-oxygen-containing material comprises hafnium oxide (HfO₂).

8. The semiconductor structure of claim 1, wherein:
the first metal is characterized by a first work function; and
the second metal is characterized by a second work function higher than the first work function.

9. The semiconductor structure of claim 1, wherein the gate comprises a titanium-containing material, a tungsten-containing material, or a molybdenum-containing material.

10. The semiconductor structure of claim 9, wherein the titanium-containing material comprises a titanium-and-nitrogen-containing material.

11. The semiconductor structure of claim 1, wherein the semiconductor structure comprises a 3D NAND structure.

12. A semiconductor processing method comprising:
providing a substrate to a processing region of a semiconductor processing chamber, wherein the substrate comprises a first layer of silicon-and-oxygen-containing material and a second layer of silicon-and-oxygen-containing material spaced a distance apart from the first layer of silicon-and-oxygen-containing material;
forming a first layer of metal-and-oxygen-containing material overlying the second layer of silicon-and-oxygen-containing material, wherein the first layer of metal-and-oxygen-containing material comprises a first metal;
forming a second layer of metal-and-oxygen-containing material overlying the first layer of metal-and-oxygen-containing material, wherein the second layer of metal-and-oxygen-containing material comprises a second metal; and
forming a gate disposed within the second layer of metal-and-oxygen-containing material.

13. The semiconductor processing method of claim 12, wherein the first layer of metal-and-oxygen-containing material and the second layer of metal-and-oxygen-containing material are formed through atomic layer deposition (ALD).

14. The semiconductor processing method of claim 12, wherein the first layer of metal-and-oxygen-containing material comprises lanthanum oxide (La₂O₃).

15. The semiconductor processing method of claim 12, wherein the first layer of metal-and-oxygen-containing material is characterized by a thickness of less than or about 20 Å.

16. The semiconductor processing method of claim 12, wherein the first layer of metal-and-oxygen-containing material comprises yttrium oxide (Y₂O₃).

17. The semiconductor processing method of claim 12, wherein the second layer of metal-and-oxygen-containing material comprises aluminum oxide (Al₂O₃).

18. The semiconductor processing method of claim 12, wherein the second layer of metal-and-oxygen-containing material is characterized by a thickness of less than or about 100 Å.

19. A semiconductor processing system comprising:
a plurality of holding chambers;
a plurality of loading chambers configured to receive substrates into a vacuum environment;
an interface section having at least two interface transfer devices configured to deliver substrates between the plurality of holding chambers coupled with the interface section at a first location of the interface section and the plurality of loading chambers coupled with the interface section at a second location of the interface section opposite the plurality of holding chambers; and
a plurality of process chambers, wherein a first process chamber of the plurality of process chambers is configured to deposit a first layer of metal-and-oxygen-containing material characterized by a first work function, and wherein a second process chamber of the plurality of processing chambers is configured to deposit a second layer of metal-and-oxygen containing material characterized by a second work function greater than the first work function over the first layer of metal-and-oxygen-containing material.

20. The semiconductor processing system of claim 19, wherein:
the first layer of metal-and-oxygen containing material comprises lanthanum oxide (La₂O₃); and
the second layer of metal-and-oxygen containing material comprises aluminum oxide (Al₂O₃).
